(19) United States
(12) Patent Application Publication
(10) Pub. No.: US 2010/0109115 A1
(43) Pub. Date: May 6, 2010

(54) Virtual IC wafers and bonding of constitutent IC films

(76) Inventor: Michael J. Ure, Cupertino, CA (US)

Correspondence Address: MICHAEL J. URE, 10518 PHIL PLACE, CUPERTINO, CA, 95014, US

(21) Appl. No.: 12/263,513

(22) Filed: Nov. 3, 2008

(51) Int. Cl. H01L 31/0352; H01L 21/304; H01L 21/67; B65G 59/00; B32B 3/20; H01L 29/00

(52) U.S. Cl. 257/443; 438/455; 257/506; 438/462; 29/25.01; 428/188; 221/92; 221/129; 257/E21.238; 257/E29.001; 257/E31.032

(57) ABSTRACT

Integrated circuits are made by bonding to a substrate one or more slices of material, and forming circuits using the slices of material.

### BACKGROUND

1. Field of the Invention

The present invention relates to the manufacture of integrated circuits.

2. State of the Art

The device layer of a typical integrated circuit (IC) extends to a depth of only about 10 microns. A semiconductor wafer, however, is typically a few hundred microns thick. The extra thickness of a semiconductor wafer leads to leakage problems. To overcome these problems, Silicon on Insulator (SOI) techniques have been developed in which a thin silicon device layer is produced on top of an insulating layer. The insulating layer is formed on a substrate, typically a silicon wafer. SOI wafers remain relatively costly, in part because of the inefficient use of silicon. For example, in one SOI technique, a thick silicon wafer is bonded to an underlying silicon wafer having an insulating layer formed thereon. The thick silicon wafer is then thinned, during which the bulk of the silicon wafer is removed, leaving only a thin device layer. Hence, the bulk of the silicon material is wasted.

The ability to form thin layers of monocrystalline silicon enables the manufacture of three-dimensional integrated circuits, as described for example in U.S. Pat. No. 6,208,545. Again, at least in some proposed techniques, the bulk of silicon material is wasted.

### SUMMARY

Integrated circuits are made by bonding to a substrate one or more slices of material, and forming circuits using the slices of material.

### DESCRIPTION OF DRAWING

The foregoing may be further understood from the following description in conjunction with the appended drawing. In the drawing:

FIG. 1A is a diagram illustrating production of thin slices of material for use in the manufacture of ICs.

FIG. 1B is a diagram illustrating production of thin slices of material for use in the manufacture of ICs.

FIG. 1C is a diagram illustrating production of thin slices of material for use in the manufacture of ICs.

FIG. 1D is a diagram of a system for producing thin slices of material for use in the manufacture of ICs.

FIG. 2 is a perspective view of a bar of material.

FIG. 3A is a diagram illustrating lithographic pre-kerfing of a first side of a body of material.

FIG. 3B is a diagram illustrating lithographic pre-kerfing of a second side of a body of material.

FIG. 3C is a diagram illustrating cutting of a bar of pre-kerfed material from the larger body.

FIG. 4A is a diagram illustrating an implant step of a kerf-free wafering and dicing technique.

FIG. 4B is a diagram illustrating a scribing step of a kerf-free wafering and dicing technique.

FIG. 4C is a diagram illustrating a cleaving step of a kerf-free wafering and dicing technique.

FIG. 5 is a diagram illustrating filling of a template with thin slices of material.

FIG. 6 is a diagram of a cross-section of the template of FIG. 5.

FIG. 7 is a diagram of a lifting operation in which a virtual wafer is lifted.

FIG. 8A is a diagram of a first bonding operation in which a virtual wafer is bonded.

FIG. 8B is a diagram of an alternative bonding operation in which a virtual wafer is bonded.

FIG. 9 is a diagram of a three-dimensional IC formed using multiple virtual wafer layers.

FIG. 10 is a diagram illustrating conceptually the use of virtual wafers and the bonding of constituent films in integrated circuit manufacture.

FIG. 11 is a diagram of an apparatus for forming an uninterrupted sheet of material from the thin slices.

FIG. 12 is a diagram of a template only partially populated with recesses.

FIG. 13 is a diagram of a large-area image sensor that may be formed using the described techniques.

FIG. 14A is a diagram of an example of a dispensing apparatus.

FIG. 14B is a timing diagram used to explain the operation of the apparatus of FIG. 14A.

FIG. 15 is a plan view of a template having only corner features defined.

### DETAILED DESCRIPTION

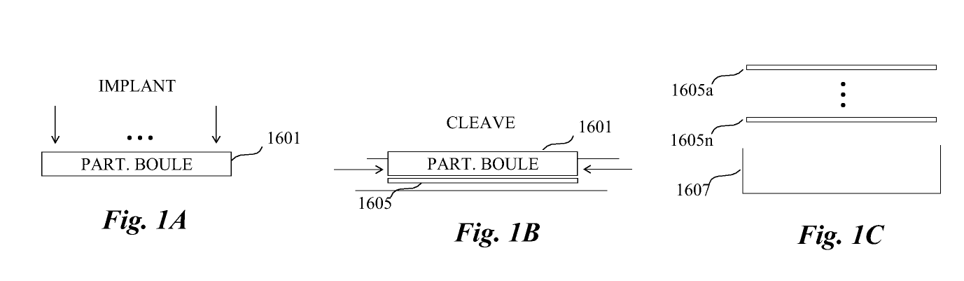

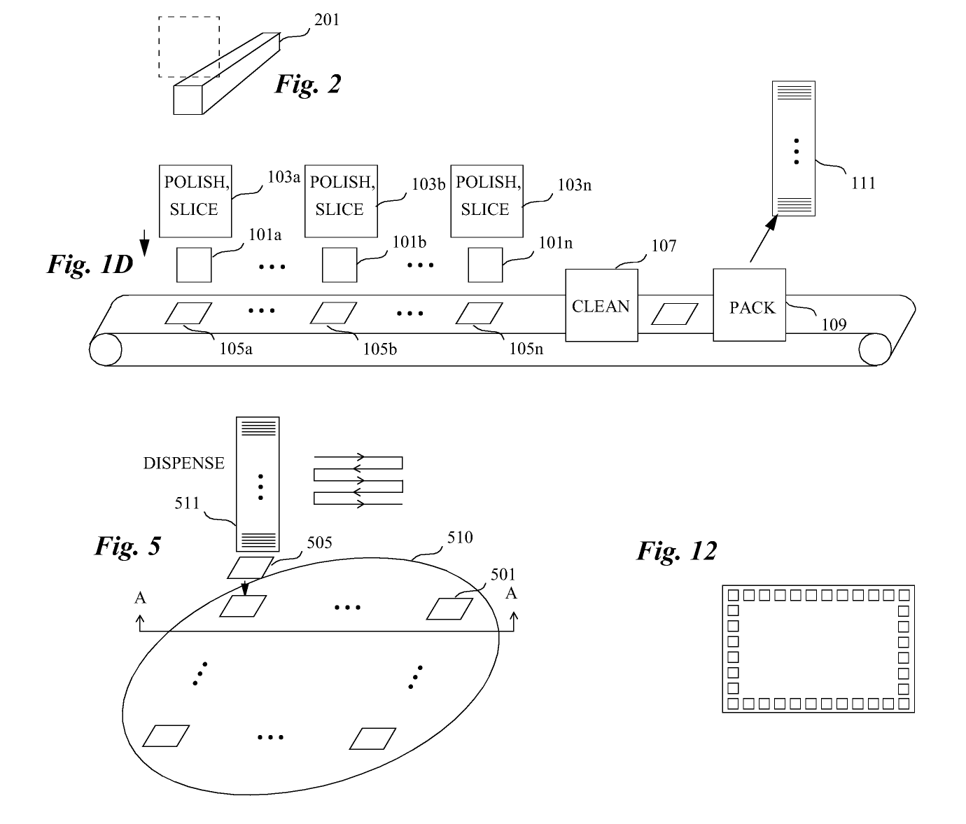

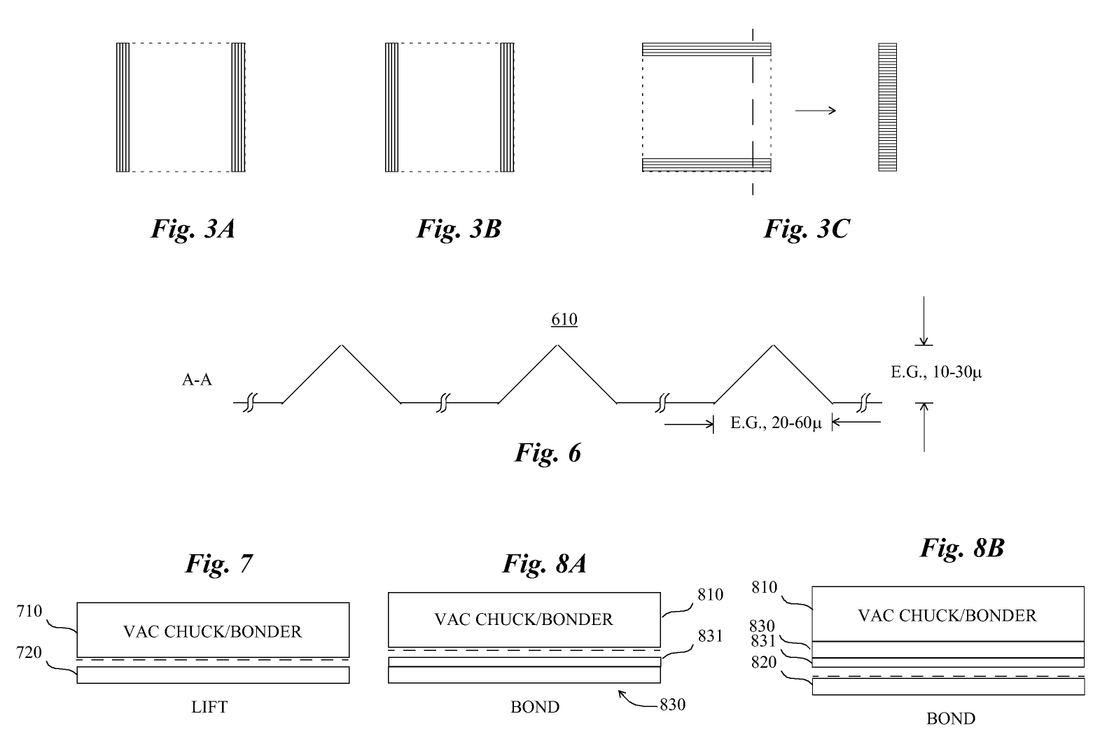

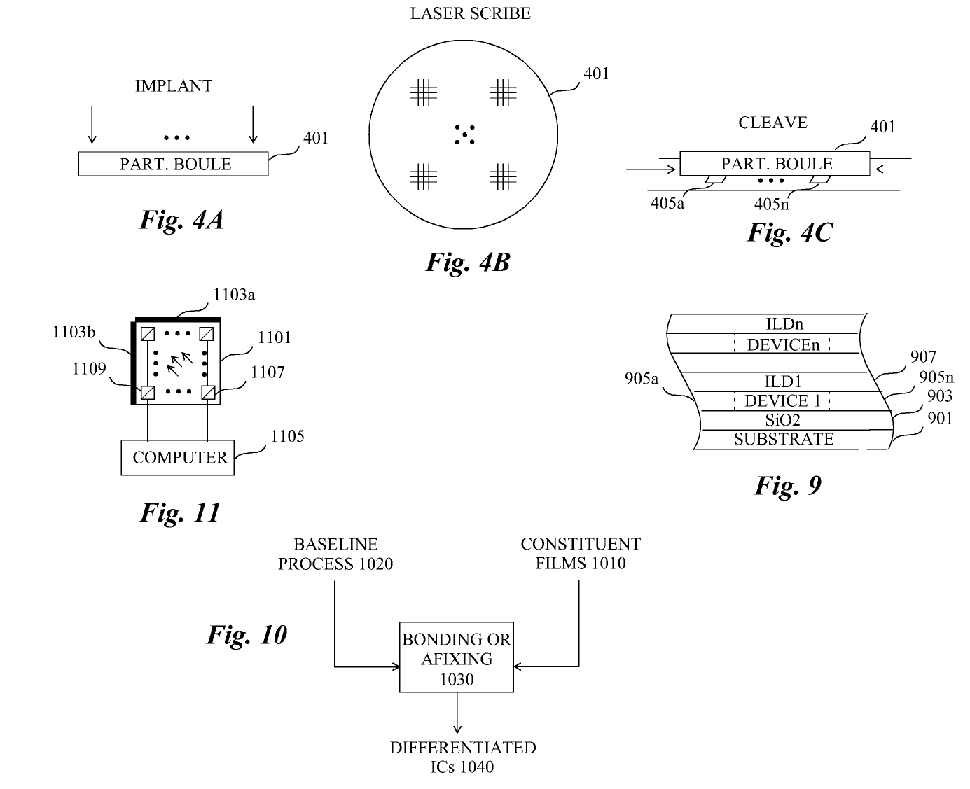

Referring to FIG. 1A-1C, diagrams are shown illustrating production of thin slices of material for use in the manufacture of ICs. In the illustrated embodiment, cleavage may be used (instead of cutting) to produce thin slices of material for use in the manufacture of ICs. A “kerf-less wafering” technique of a type licensed by Silicon Genesis Corporation of San Jose, Calif. may be adapted for this purpose. In FIG. 1A, an implant process is used to form in a body of material (partial boule) 1601 an implant layer at a desired depth. In FIG. 1B, a cleaving process is used to cleave the material at the implant layer, thereby freeing a small slice of material 1605. Such a kerf-free process is generally capable of producing thin slices of 50 microns or less in thickness. Multiple such thin slices of material 1605a-1605n are then packed together in a package 1607, using suitable separator layers if desired. During the manufacture of ICs, a thin slice of material may be lifted (using a vacuum chuck/bonder, for example) and bonded to a suitable bonding layer as described in greater detail hereinafter. Through silicon vias may be used to form interconnections to circuitry formed on an underlying layer. In this manner, three-dimensional circuits having an arbitrary number of layers may be produced.

The body of material 1601 may be polished prior to separating of the slice of material 1605. Furthermore, if desired, a holder may be used to also polish the opposite side of the slice of material 1605 such that both sides of the slices 1605a-1605n are polished. During the manufacture of ICs, then, the slices may be used without the need to interrupt the main flow of manufacture for thinning, polishing, etc.

Referring now to FIG. 1D, there is illustrated in simplified form an alternative system for producing thin slices of material for use in the manufacture of ICs.

In an exemplary embodiment, multiple bars of material of precise dimensions are provided. The bars may be bars of monocrystalline silicon for example, sawn from an ingot or boule and polished to precise dimensions. Alternatively, the bars may be of a permanent magnetic material, or any other material used in the manufacture of ICs, including metals, metalloids, insulators, etc. The bars may be of similar dimensions as finished IC die, for example 1 cm×1 cm, or multiples thereof, e.g., 2×2 cm, 3×3 cm, 4×4 cm, etc. Alternatively, the bars may be of dimensions that are multiples of a finished IC die. One such bar 201 is illustrated in perspective in FIG. 2. Corners of the bars may be slightly chamfered or rounded as needed.

In the case of crystalline materials, the bars may be sawn from a crystal ingot or boule in such a way to achieve a desired crystal orientation of the slices sliced from the bars. Alternatively, for materials having a “soft” axis and a “hard” axis, the orientation may be such as to make cutting easier.

In correspondence to each of the bars is provided machinery 103a-103n for polishing the ends of the bars and for slicing thin slices of polished material 105a-105n from the ends of the bars. One technique for slicing a thin slice from the end of a bar uses Wire Electrical Discharge Machining (WEDM), as described for example in Appendix 1. In the present application, the wire is preferably about 10 microns thick. Any of various other cutting methods may be applied, including abrasion, ablation (e.g., laser cutting), etc.

To facilitate cutting using some cutting methods, lithographic “pre-kerfing” may be used as illustrated in FIGS. 3A-3C. Parallel kerf lines are etched throughout the surface of a body of material (FIG. 3A) having a thickness equal to a desired thickness of the bars of FIG. 1. Optionally, identical kerf lines may be etched into an opposite side of the body of material (FIG. 3B), with the kerf lines on opposite sides being aligned. The kerf lines may, for example, be located on 20 micron centers and may be about ten microns wide and 10 microns deep. The material may then be cut into bars (FIG. 3C). Optionally, kerf lines may be etched into all four sides of a body of material. In order to do so, the bars of material may first be cut and then “formed up” using a fixture so that lithographic pre-kerfing may be performed. Such lithographic pre-kerfing may be applied to each side of the material in turn.

The slices of material may be of uniform thickness or may be of varying thickness or tapered.

In other embodiments, cleavage may be used instead of cutting. A “kerf-less wafering” technique of a type licensed by Silicon Genesis Corporation of San Jose, Calif. may be adapted for this purpose as illustrated in FIGS. 4A-4C. In FIG. 4A, an implant process is used to form in a body of material an implant layer at a desired depth. In FIG. 4B, unlike the Silicon Genesis process, laser scribing or other scribing is used to scribe the material into small regions to the depth of the implant layer. Then, in FIG. 4C, a cleaving process is used to cleave the material at the implant layer, thereby freeing a multitude of small slices of material 405a-405n. Such a kerf-free process is not applicable to non-crystalline materials and may or may not be capable of producing very thin slices of 10 microns in thickness, or, more generally, about 10-30 microns in thickness.

Alternatively, scribing may be omitted, and kerf-less wafering may be applied repeatedly to a disk of material, resulting in many thin whole-wafer layers. These layers may be packaged together and kept at the ready during IC manufacture for use in the manufacture of 3D ICs. A vacuum chuck/bonder may be used to lift a thin whole-wafer layer, align it with a wafer in progress, and bond it to a suitably prepared surface as described in greater detail hereinafter in relation to arrayed slices of material.

Referring again to FIG. 1, the slices are conveyed to a station 107 where they are cleaned to remove any residue or particles from the slicing operation. Any of various types of conveyance mechanisms may be used for this purpose. In one embodiment (not shown), an enclosed plexiglass or similar conveyance structure is used in which controlled fluid motion entrains the slices and conveys them downstream. Cleaning may be wet, dry (e.g., electrostatic), or any combination of the foregoing or other cleaning methods.

The cleaned slices are then conveyed to a further station 109 where they are packed together in a stack 111 containing a large number of slices (e.g., tens of thousands). If needed, the slices may be packed with polished surfaces face-to-face to avoid possible marring of the polished faces.

Referring now to FIG. 5, the thin slices are dispensed from a pack 511 into a template 510 having an array of shallow depressions, each depression being designed to receive a thin slice 505. (If the slices are packed face-to-face, then a particular slice may need to be flipped during this dispensing.) Dispensing may be accomplished using a sequence of air knives, for example, or other known techniques. Of course, the slices may also be dispensed by hand.

Referring to FIG. 14A, a diagram is shown of an example of one dispensing mechanism. Pressure rollers 1401a, 1401b are advanced by minute increments in order to release a small number of slices into a separating section 1403. Air knives AK1 and AK2 (indicated schematically) are used to isolate a single slice 1405. The single slice 1405 is then released into a flipping section 1407. A retractable, non-marring member 1409 is selectively inserted into the path of the single slice 1405, and, together with an air jet AIR, causes the single slice 1405 to flip. The flipped single slice is retained and stabilized by an air knife AK0 and then released for final dispensing. A timing sequence that may be used to energize and de-energize the air knives is illustrated in FIG. 14B.

A cross-section of an example of a template 610 is shown in FIG. 6. The template may be formed lithographically by processing a semiconductor wafer, for example. The template may have one or more through holes formed in each depression to allow suction to be applied. A slice may be positioned within an opposing depression through any combination of suction, vibration, etc. A single dispenser may scan the entire template to deposit a slice within each depression throughout the template. Alternatively, an array of dispensers may work in concert to complete the filling of the template more quickly. Filling of the template may be performed “off-line” but nearby during the processing of IC wafers such that, on a per-wafer basis, a single template or a few templates may be reused and a filled template is available when needed.

In an alternative embodiment, illustrated in FIG. 11, instead of a template a smooth vibration plate 1101 is provided having edge stops 1103a, 1103b. The plate is supported in an orientation that is tilted from horizontal as indicated by the arrows. Thin slices may be dispensed in a scanning sequence that progresses in a sequence of scans perpendicular to the arrows in a general direction opposite to the direction of the arrows. As the slices are dispensed they are vibrated into place. The vibration plate may be arranged such that vibrational energy is applied selectively in small areas under computer control (computer 1105) in the vicinity of the scanning edge, using an array of energy transducers 1107. The plate may have holes formed throughout to allow suction to be applied via localized vacuum chuck elements. When one of the thin slices has been placed, suction is applied to fix the slice in place. In this manner, the thin slices may be positioned close together, edge-to-edge to form a substantially uninterrupted, though patchwork, sheet of material. After all of the thin slices have been placed, the edge stops, if needed, may then be removed.

Similar computer-controlled, localized vibration/vacuum arrangements may be applied to templates like the template of FIG. 3.

A plan view of another type of template 1500 is shown in FIG. 15. The template is designed to be filled with slices having chamfered or rounded corners and is provided with corner features 1501. The corner features may have a height that is a few microns less than the thickness of the slices. The corner features may taper outwardly from top to bottom. The features and techniques previously described in relation to templates may be applied to the template 1500. Slices may be dispensed and vibrated into place and held in place using vacuum suction so as to form a substantially uninterrupted virtual wafer. The template may be formed using lithography, known machining techniques, or any combination thereof. If desired, the bonding face of the slices may be polished at this stage. Furthermore, prior polishing may be avoided and both faces of the slices may be polished at this stage by polishing one face, transferring the slices to an identical template, and polishing the other face.

A template may be only partially populated with recesses as illustrated in FIG. 12. Such a template may be used, for example, to bond semiconductor slices to the periphery of display structures to enable integrated circuits to be formed and interconnected therein.

At the appropriate point in the IC manufacturing process, a vacuum chuck and bonder 710 is aligned with the filled plate or template 720 and lifts the thin slices from the plate or template (FIG. 7). The vacuum chuck and bonder is then aligned with an IC wafer or other substrate (830, FIG. 8A). The substrate is assumed to have a top-most layer 831 (of an insulator or of a metal) that will readily bond to the slices, for example through the application of heat and pressure. One example of such bonding is thermocompression bonding, or the type of bonding used currently to produce SOI wafers. For example, if the slices are formed of monocrystalline silicon and the top-most layer is silicon dioxide or silicon nitride, the slices may be readily bonded to desired locations using thermocompression bonding. Other types of bonding include thermal diffusion bonding and anodic bonding. The slices may be bonded to the substrate using these types or other types of bonding mechanisms; alternatively, the slices may be fixed to the substrate, permanently or temporarily, using other non-bonding mechanisms-even using a vacuum chuck, for example.

Alternatively, as illustrated in FIG. 8B, the filled template 820 is left undisturbed, and the wafer in progress 830 is lifted by the vacuum chuck/bonder 810 and bonded to the slices held by the template. Heat may be applied through the medium of the template. In this instance, the depressions of the template may be more shallow to allow the tops of the slices to protrude sufficiently to allow them to be bonded to. Furthermore, in this instance, the template is filled with slices having polished faces facing down, such that the unpolished faces are bonded to. Alternatively, polishing may be performed after bonding, simplifying polishing as well as packing and dispensing.

The substrate may be a semiconductor substrate or a non-semiconductor substrate. An example of the latter is borosilicate glass, or BSG. BSG engineered to have a coefficient of thermal expansion (CTE) closely matching that of silicon is available from Hoya Corporation USA of Fremont, Calif.

Following bonding, if the slices are semiconductor material, a mask layer deposition step will typically follow. Surface planarization may be performed at this point or at a subsequent point.

A cross section of a portion of an example of a three-dimensional IC wafer that may be formed using the foregoing techniques is shown in FIG. 9. A substrate 901 has formed thereon an insulating layer 903 such as a layer of silicon dioxide. On top of the silicon dioxide layer are bonded slices of semiconductor material 905a-905n. These slices may together be regarded as a “virtual wafer.” (In packed form, a virtual wafer may occupy a small volume, for example 1 cm³.) A first device layer, DEVICE 1, is formed within this virtual wafer. Devices of the first device layer are interconnected through an interlayer dielectric layer 907, ILD1 containing metal wiring. There follow successive device layers and ILD layers. Because of the thinness of the virtual wafer layers, interconnections may be readily formed between ILD layers, using through-silicon vias or the like.

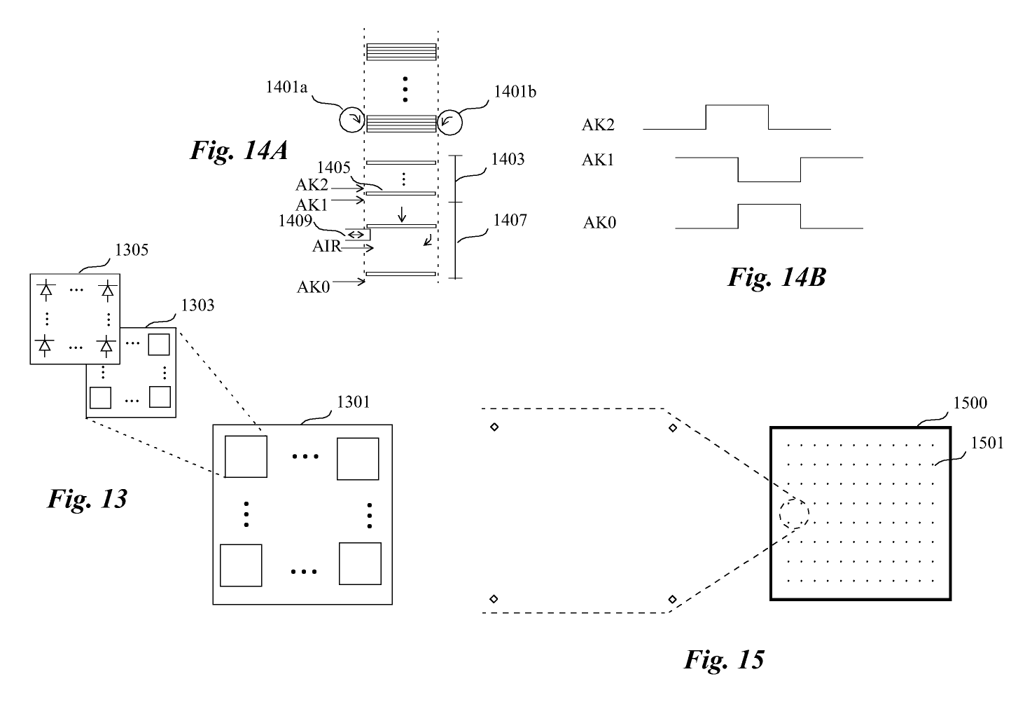

An example of a large-area image sensor that may be formed using the foregoing techniques is shown in FIG. 13. The image sensor is composed of an array circuit tiles 1301, each circuit tile having a first circuit layer 1303 composed of an array of control and readout circuits and a second circuit layer 1305 composed of an array of photodiodes, the second layer overlying the first layer.

Application of the foregoing techniques to IC manufacture results in a much more efficient use of semiconductor material (even after accounting for losses during sawing bars from an ingot or boule in the case of crystalline material). The resulting “silicon gain” may be applied with particular advantage to other materials besides silicon, including, for example, germanium, gallium arsenide, etc. Moreover, the foregoing techniques allow for the modularization of the IC manufacturing process. New materials can be incorporated into integrated circuits without extensive process modifications. Materials that cannot be readily formed using common deposition processes may be used.

FIG. 10 illustrates this concept. Constituent films 1010 are bonded or affixed to substrates processed using a baseline manufacturing semiconductor process 1020 through a bonding or fixing process 1030 to produce differentiated integrated circuits 1040.

Although embodiments of the present invention have been described in detail, it should be understood that various changes, substitutions and alternations can be made without departing from the spirit and scope of the inventions as defined by the appended claims. Unless otherwise defined therein, words of approximation are taken to mean values within a 25% range of a specified value.

APPENDIX 1: http://www.physorg.com/news140673133.html (7 Oct. 2008) University of Utah engineers devised a new way to slice thin wafers of the chemical element germanium for use in the most efficient type of solar power cells. They say the new method should lower the cost of such cells by reducing the waste and breakage of the brittle semiconductor.

The expensive solar cells now are used mainly on spacecraft, but with the improved wafer-slicing method, “the idea is to make germanium-based, high-efficiency solar cells for uses where cost now is a factor,” particularly for solar power on Earth, says Eberhard “Ebbe” Bamberg, an assistant professor of mechanical engineering. “You want to do it on your roof.”

Dinesh Rakwal, a doctoral student in mechanical engineering, adds: “We're coming up with a more efficient way of making germanium wafers for solar cells—to reduce the cost and weight of these solar cells and make them defect-free.”

Bamberg and Rakwal are publishing their findings in the Journal of Materials Processing Technology. Their study has been accepted, and a final version will be published online late this month or in early October, and in print in 2009.

Brass-coated, steel-wire saws now are used to slice round wafers of germanium from cylindrical single-crystal ingots. But the brittle chemical element cracks easily, requiring broken pieces to be recycled, and the width of the saws means a significant amount of germanium is lost during the cutting process. The sawing method was developed for silicon wafers, which are roughly 100 times stronger.

The new method for slicing solar cell wafers—known as wire electrical discharge machining (WEDM)—wastes less germanium and produces more wafers by cutting even thinner wafers with less waste and cracking. The method uses an extremely thin molybdenum wire with an electrical current running through it. It has been used previously for machining metals during tool-making.

Germanium serves as the bottom layer of the most efficient existing type of solar cell, but is used primarily on NASA, military and commercial satellites because of the high expense—raw germanium costs about $680 per pound. Four-inch-wide wafers used in solar cells cost $80 to $100 each, and the new cutting method may reduce the cost by more than 10 percent, says Grant Fines, chief technology officer for germanium wafer-maker Sylarus Technologies in St. George, Utah.

“Anything that can be done to lower this cost ultimately will lower the cost of solar power per kilowatt-hour, which is beneficial,” and will encourage wider use of solar power, he adds. “That's why this technology Ebbe has come up with is very intriguing.”

Sylarus is considering using the new method, but must determine if it can be scaled up so wafers can be mass-produced in a commercially viable manner, Fines says. Bamberg's method would “reduce the amount we have to recycle and increase the yield,” he adds. “It has the potential to give good savings, which helps enable this technology here on Earth.”

A patent is pending on a way of using the new method so that multiple, parallel electrically charged wires are used to cut germanium wafers—a mass-production method Bamberg compares with an egg slicer.

### Bringing High-Efficiency Solar Cells Down to Earth

Germanium is a semiconductor at the bottom of “multijunction” solar cells. Above it are layers of gallium-indium-arsenide and gallium-indium-phosphide. The layers work together to capture different wavelengths of sunlight, and the germanium also serves as the substrate upon which the solar cell is “grown.”

When sunlight hits a solar cell, the energy is converted to a flow of electrons in the cell, namely, electricity.

Silicon-based solar cells on Earth have maximum efficiency of 20 percent, Fines says. In space, germanium solar cells typically convert 28 percent of sunlight into electricity, but on Earth where solar concentrators are used, they can convert more than 40 percent of sunlight into electricity, and their efficiency theoretically exceeds 50 percent, he adds. Despite the greater efficiency of germanium-based solar cells, a 2005 survey found that 94 percent of solar cells made for non-space uses were silicon-based because silicon is much cheaper and less fragile than germanium, the Utah researchers say.

Bamberg says germanium-based solar cells are used on most spacecraft because they are more efficient and lighter than silicon-based solar cells. By making it more attractive economically to use efficient germanium solar cells on rooftops, the weight and size of solar panels can be reduced “so it doesn't bother you aesthetically,” he adds.

The new method may make germanium-based solar cells competitive with less efficient but less expensive silicon-based solar cells for uses on Earth, says Bamberg.

In the new method, the molybdenum wire essentially is an electrode, and it is connected to a pulsed power supply that charges the wire during the cutting process.

A cylinder-shaped germanium ingot rests on a horizontal support, and the wire is lowered into the ingot as new wire is pulled continually from a supply spool to replace the cutting wire as it wears. Thin, synthetic oil is injected along the wire, both to increase the electrical charge on the wire and to flush away material that melts during the cutting process.

The process is slow. Wire electrical discharge machining takes 14 hours to cut a single wafer. Bamberg says the electrified wire method has to be done gently to avoid cracking the germanium, but he hopes to increase the speed to the six hours it now takes to cut a wafer using a wire saw.

Wire saws made of brass-coated steel have a thickness of about 170 or 180 microns (millionths of a meter). The Utah researchers used molybdenum wire 75 to 100 microns thick, a bit thicker than a human hair. Less germanium is wasted during the slicing process because the electrified cutting wire is thinner.

The study found that a 100-micron-thick electrified wire significantly reduced the waste and increased the number of wafers that could be made from a germanium ingot, but a thinner 75-micron-wide wire did even better.

“At the current standard wafer thickness of 300 microns, you can produce up to 30 percent more wafers using our method” with a 75-micron-wide wire, Bamberg says. “Since we produce them crack free, we can also make them thinner than standard techniques. So if you go down to a 100-micron-thick wafer, you can make up to 57 percent more wafers [from the same germanium ingot]. That's a huge number.”

Making the wafers thinner will reduce their cost because more can be made from the same ingot, he adds.

The new study found that the “kerf” —which is the amount of germanium wasted during the slicing process—was 22 percent less when a 75-micron diameter electrified wire was used to cut the wafers, compared with the conventional wire saw method. The researchers cut 2.6-inch-diameter wafers with a thickness of 350 microns.

The study also showed less germanium was wasted not only using the smaller wire size, but also if the charge on the electrified wire was lower.

Source: University of Utah

What is claimed is:

1. A method of making an integrated circuit comprising:
obtaining one or more slices of material from a package of multiple slices of material;
fixing to a substrate said one or more slices of material; and
forming circuits using said one or more slices of material.

2. A product produced by the steps of:
obtaining one or more slices of material from a package of multiple slices of material;
fixing to a substrate said one or more slices of material; and
forming circuits using said one or more slices of material.

3. A stacked integrated circuit comprising:
a substrate;
a first array of separate slices of material fixed to the substrate;
a second array of separate slices of material fixed to the substrate; and
an inter-layer dielectric structure positioned between said first array and said second array;
wherein the separate slices of material of said first array and said second array slices each have a thickness of about 10 to 30 microns and an area of at least 1 mm².

4. A virtual wafer comprising:
an array of separate slices of material selected for electrical properties of the material, the slices each having a thickness of about 10 to 30 microns and an area of at least 1 mm²; and
a support for holding each slice of material in a fixed position in relation to other slices of material.

5. A package of separate slices of material selected for electrical properties of the material, the slices each having a thickness of about 10 to 30 microns and an area of at least 1 mm², the slices of material being stacked one on top of the another.

6. A method comprising:
forming separate slices of material selected for electrical properties of the material, the slices each having a thickness of about 10 to 30 microns and an area of at least 1 mm²;
cleaning the slices; and
packing the slices such that the slices of material are stacked one on top of the another.

7. A template for use in making integrated circuits, the template comprising an array of depressions for receiving separate slices of material, the depressions each having a depth of about 10 to 30 microns and an area of at least 1 mm².

8. An apparatus for use in making integrated circuits, comprising:
a plate supported in an orientation that is tilted from horizontal;
an edge stop attached to an edge of the plate; and
a computer-controlled array of energy transducers coupled beneath the plate.

9. A method of forming an array of separate slices of material using a plate or template, the method comprising:
dispensing a slice of material above a desired location of the plate or template;
situating the slice of material within the desired location; and
repeating the foregoing steps for additional slices of material;
wherein the material is selected for electrical properties of the material, and the slices each have a thickness of about 10 to 30 microns and an area of at least 1 mm².

10. A method of making thin slices of material, comprising:
lithographically pre-kerfing a body of material in a first direction;
cutting the material into smaller of bodies of material in a second direction perpendicular to the first direction; and
cutting the smaller bodies of material into slices having a thickness of about 10 to 30 microns.

11. A product produced by the process of:
lithographically pre-kerfing a body of material in a first direction;
cutting the material into smaller of bodies of material in a second direction perpendicular to the first direction; and
cutting the smaller bodies of material into slices having a thickness of about 10 to 30 microns.

12. A stacked image sensor comprising:
an array of circuit tiles, each circuit tile comprising a first circuit layer comprising an array of control and readout circuits and a second circuit layer comprising an array of photodiodes, the second layer overlying the first layer.

13. An apparatus for dispensing slices of material selected for electrical properties of the material, the slices each having a thickness of about 10 to 30 microns and an area of at least 1 mm², the apparatus comprising:
a separating section for isolating a single slice of material from a stack of slices of material; and
a flipping section coupled to the separating section for flipping selected ones of the slices of material.

14. A method of making an integrated circuit comprising:
lifting a thin, unattached whole-wafer layer of material;
bonding the whole-wafer layer of material to an integrated circuit wafer having integrated circuits formed thereon; and
forming circuits using the whole-wafer layer of material.

15. A product produced by the steps of:
lifting a thin, unattached whole-wafer layer of material;
bonding the whole-wafer layer of material to an integrated circuit wafer having integrated circuits formed thereon; and
forming circuits using the whole-wafer layer of material.

16. A template for use in making integrated circuits, the template comprising an array of corner features for receiving separate slices of material having chamfered or rounded corners, the corner features each having a height of about 10 to 30 microns, a group of four adjoining corner features defining an area therebetween of at least 1 mm².

17. The method of claim 1, wherein the one or more slices of material comprises an array of separate slices of material.

18. The product of claim 2, wherein the one or more slices of material comprises an array of separate slices of material.
